(19) United States
(12) Patent Application Publication
(10) Pub. No.: US 2010/0326516 A1
(43) Pub. Date: Dec. 30, 2010

(54) PHOTOELECTRIC TRANSFER DEVICE

(75) Inventor: Masahiro Morooka, Kanagawa (JP)

Correspondence Address: WOLF GREENFIELD & SACKS, P.C., 600 ATLANTIC AVENUE, BOSTON, MA, 02210-2206, US

(73) Assignee: Sony Corporation, Tokyo (JP)

(21) Appl. No.: 12/876,784

(22) Filed: Sep. 7, 2010

Related U.S. Application Data
(63) Continuation of application No. 10/542,193, filed on Jul. 14, 2005.

(30) Foreign Application Priority Data
Jan. 15, 2003 (JP) JP2003-006914

(51) Int. Cl. H01L 31/0216

(52) U.S. Cl. 136/256

(57) ABSTRACT

In a photoelectric transfer device having a semiconductor electrode composed of semiconductor nanoparticles and an electrolyte layer between a pair of transparent conductive substrates, a transparent conductive substrate at the light-receiving side is made by stacking a transparent substrate, conductive wiring layer and a metal oxide layer in order from the light-receiving side and having sheet resistance equal to or lower than 10Ω/□. The metal oxide layer is made of an In—Sn composite oxide, SnO₂, TiO₂, ZnO, or the like.

### CROSS REFERENCES TO RELATED APPLICATIONS

This application is a continuation of prior application Ser. No. 10/542,193, filed Jul. 14, 2005, which, in turn, claims priority under 35 U.S.C. 371 and 37 CFR 1.495 to PCT/JP2003/016730, filed Dec. 25, 2003, which claims the priority benefit of Japanese patent application number 2003-006914, filed in the Japanese Patent Office on Jan. 15, 2003, each of which is hereby incorporated by reference to the maximum extent allowable by law.

### TECHNICAL FIELD

The present invention relates to a photoelectric transfer device especially suitable for application to wet solar cells.

### BACKGROUND ART

It is generally recognized that the use of fossil fuel such as coal and petroleum as energy sources invites global warming by resultant carbon dioxide. The use of atomic energy accompanies the risk of contamination by radioactive rays. Currently under various discussions on the environmental issues, dependence upon these kinds of energy is undesirable.

On the other hand, solar cells, which are photoelectric transfer devices for converting sunlight to electric energy, use sunlight as their energy resources, and they produce only a small adverse effect to the global environment. Therefore, wider distribution of solar cells is anticipated.

Although there are various materials of solar cells, a number of solar cells using silicon are commercially available. These solar cells are roughly classified to crystalline silicon solar cells using single crystal or polycrystal and amorphous silicon solar cells. In conventional solar cells, single crystal silicon or polycrystal silicon, i.e. crystalline silicon, has been used often.

In crystalline silicon solar cells, photoelectric transfer efficiency, which represents the performance of converting light (sun) energy to electrical energy, is higher than that of amorphous silicon solar cells. However, since crystalline silicon solar cells need much energy and time for crystal growth, they are disadvantageous from the viewpoint of their costs.

Amorphous silicon solar cells are advantageous in higher light absorption, wider selectable range of substrates and easier enlargement of the scale.

However, photoelectric transfer efficiency of amorphous silicon solar cells is lower than that of crystalline silicon solar cells. Furthermore, although amorphous silicon solar cells are higher in productivity than crystalline silicon solar cells, they need an evacuation process for the manufacture. Therefore, the burden related to facilities for fabrication of crystalline silicon solar cells is still heavy.

On the other hand, there have been long researches in solar cells using organic materials toward more cost reduction of solar cells. However, they exhibit as low photoelectric transfer coefficient as 1%, and involve difficulties in durability as well.

Under the circumstances, an inexpensive solar cell using dye-sensitized porous semiconductor particles was introduced in Nature 353, p. 737, 1991. This is a wet solar cell, i.e. an electrochemical photocell whose photo electrode is a titanium oxide porous film spectrally sensitized by using ruthenium complex as a sensitizing dye. This solar cell has advantages in that inexpensive oxide semiconductors such as titanium oxide can be used; light absorption of the sensitizing dye ranges widely over the visible wavelength up to 800 nm; and quantum efficiency of the photoelectric transfer is high enough to realize high energy conversion efficiency. Moreover, because the solar cell does not need a process in a vacuum for its manufacture, it does not require bulky facilities or equipment.

If this solar cell is large-scaled (widened in area), it is difficult to realize a favorable photoelectric transfer efficiency by using a commercially available resistant-to-oxidization transparent conductive substrate because it has a high sheet resistance and causes a loss of fill factor. Therefore, to make a large-scale solar cell, it is necessary to take measures for patterning highly conductive metal or carbon wiring on the substrate to reduce the sheet resistance of the transparent conductive substrate.

In this solar cell, however, its electrolyte contains iodine and/or other halogens. Therefore, it involves the problem of dissolution or disconnection of wirings by corrosion and breakdown of wirings by dissolution of base metals. Thus, the solar cell seriously deteriorates in characteristics with time. Even when a metal excellent in corrosion resistance is used as the wiring material, its direct contact with the wirings and the electrolyte causes and retains the problem of so-called reverse electron transfer where electrons injected into the semiconductor and reaching the wirings deoxidize the electrolyte before flowing out to the external circuit.

It is therefore an object of the invention to provide a photoelectric transfer device free from reverse electron transfer reaction, excellent in durability and having high photoelectric transfer efficiency.

### DISCLOSURE OF INVENTION

To accomplish the above object, there is provided a photoelectric transfer device characterized in the use of a transparent conductive substrate made by stacking a transparent substrate, a conductive wiring layer and a protective layer in order from a light-receiving side and having sheet resistance equal to or less than 10Ω/□.

Preferably, plural lines of the conductive wiring layer are provided, and at least one line of the conductive wiring layer is bonded to a collector portion of the photoelectric transfer device to enhance the collecting efficiency. In the present invention, the term “transparent” specifies that transmittance of visible to near-infrared light having wavelengths of 400-1200 nm is 10% or more in a local or entire area. The conductive wiring layer is preferably made of a material exhibiting high electronic conductivity, which is more preferably stable electrochemically. More specifically, here is preferably used, although not limitative, a conductive material (simplex metal, alloy, etc.) containing at least one element selected from the group consisting of Pt, Au, Ru, Os, Ti, Ni, Cr, Cu, Ag, Pd, In, Zn, Mo, Al and C. Thickness of the conductive wiring layer made of such a material is not limitative. However, the thicker the layer, higher electron transfer property can be realized. However, if the layer is too thick, surface roughness will become large and will make it difficult to deposit the protective layer uniformly. In this case, the adhesiveness of the protective layer will seriously degrade. Therefore, there is a preferable thickness for the conductive wiring layer. Although there is a difference in sheet resistance attained depending upon the nature of the material, thickness of the conductive wiring layer is typically 10-10000 nm, or more preferably 50-5000 nm. There is no special limitation regarding the coverage of the conductive wiring layer relative to the photo detective surface of the light photoelectric transfer device. However, the coverage is preferably within 0.01%-50%. If the coverage is too large, detected light cannot pass through sufficiently. Therefore, the coverage is more preferably 0.1%-20%. Width of each conductive wiring layer and distance between adjacent conductive wiring layers are not limitative. The wider the width, and the narrower the distance, the electron transfer property will be enhanced. However, if the width is too wide, or if the distance is too narrow, transmittance of incident light will decrease. Therefore, there are preferable values for them. Width of each conductive wiring layer is typically 1-1000 μm, and preferably 10-500 μm. Distance between adjacent conductive wiring layers is typically 0.1-100 mm, and preferably 1-50 mm. Any method may be used to form the conductive wiring layers on the transparent substrate among vapor deposition, ion plating, sputtering, CVD, plating, dispersion coating, dipping, spinner technique, and other known techniques. To enhance the adhesiveness of the conductive wiring layers to the transparent substrate, a more adhesive base material may be interposed between the conductive wiring layers and the transparent electrode. The conductive wiring layers may be patterned by any method among laser cutting, etching, lift-off, and other known techniques.

The protective layer has the role of blocking the conductive wiring layers from the electrolyte and preventing reverse electron transfer and corrosion of the conductive wiring layers. The protective layer is preferably excellent in electron transfer (not only by normal electric conduction but also by tunneling) and transparent. Subject to these requirements, the protective layer may be made of any material, and may have either a single-layered structure or a multi-layered structure including at least two layers made of different materials. A metal oxide layer is typically used as the protective layer, but a metal nitride layer such as TiN, WN, or the like, may be used as well. Examples of metal oxides are In—Sn composite oxides (ITO), SnO₂ (including those doped with fluorine or the like), TiO₂, ZnO, and others. Although these are not limitative materials, at least one of them is preferably contained. There are no special restrictions regarding the thickness of the metal oxide layer. However, if the metal oxide layer is too thin, it will not be able to block the conductive wiring layers from the electrolyte effectively. If the metal oxide layer is too thick, the transmittance will decrease. In this sense, there is a preferable value of the thickness. The thickness is typically 1-5000 nm, and preferably 10-1000 nm. To enhance the resistance to oxidization, some of the above metal oxides may be stacked, if necessary.

The transparent substrate may be made of any material among various base materials provided it is transparent. The transparent substrate is preferably good in blockage of moisture and gas intruding from the exterior of the photoelectric transfer device, resistance to the solvent, weatherability, and so on. Candidates include transparent inorganic substrates of quartz, glass, or the like, transparent plastic substrates of polyethylene terephthalate, polyethylene naphthalate, polycarbonate, polyethylene, polypropylene, polyphenylene sulfide, polyvinylidene fluoride, tetraacetyl cellulose, phenoxy bromide, aramid, polyimide, polystyrene, polyarylate, polysulfone, polyolefin, and so forth. Although they are not restrictive, substrates exhibiting high transmittance to visible light are especially preferable. Taking easier workability and lighter weight into account, transparent plastic substrates are preferable candidates. There are no specific limitations on the thickness of the transparent substrate. The thickness is determined as desired, depending upon the light transmittance, blocking capability between the interior and the exterior of the photoelectric transfer element, and other factors.

Usable materials of semiconductor nanoparticles are elementary semiconductors represented by silicon, various compound semiconductors, compounds having a perovskite structure, and so forth. These semiconductors are preferably n-type semiconductors in which electrons in the conduction band behave as carriers and provide an anode current when excited by light. Examples of such semiconductors are metal oxides such as TiO₂, ZnO, WO₃, Nb₂O₃, TiSrO₂ and SnO₂. Among them, TiO₂ is especially desirable. However, usable semiconductors are not limited to those suggested above, and two or more of them may be used in mixture.

The semiconductor layer (semiconductor electrode) composed of semiconductor nanoparticles may be made by any technique. However, when physical properties, convenience, manufacturing costs, etc. are taken into consideration, wet film-forming methods are preferable. Especially recommended is a method of preparing a paste prepared by uniformly dispersing semiconductor nanoparticles in powder or sol into water or other solvent coating it on the transparent conductive substrate. Any coating method may be used here for example among dipping, spraying, wire bar technique, spin coating, roller coating blade coating, gravure coating and other known techniques. Alternatively, any wet printing method can be used for example among relief printing, offset printing, gravure printing, intaglio printing, rubber plate printing, screen printing, and so forth. In the case where crystalline titanium oxide is used as the material of the semiconductor nanoparticles, it preferably has an anatase crystal structure from the photocatalytic standpoint. Anatase-type titanium may be commercially available powder, sol or slurry, or may be uniformed in grain size by a known technique such as hydrolyzing titanium oxide alcoxide. In the case where commercially available powder is used, secondary agglomeration of particles is preferably prevented. For this purpose, the powder preferably undergoes grinding of particles in a mortar or a ball mill upon preparation of the coating liquid. In this process, to prevent that particles once released from secondary agglomeration agglomerate again, acetyl acetone, hydrochloric acid, nitric acid, surfactant, chelating agent, or the like, may be added. Furthermore, to enhance the viscosity, any thickening agent among polymers such as polyethylene oxide and polyvinyl alcohol or cellulose-based viscosity improvers, for example, may be added.

There are no special restrictions regarding the grain size of the semiconductor nanoparticles. However, the grain size is preferably 1-200 nm and more preferably 5-100 nm in average grain size of primary particles. It is also possible to mix semiconductor nanoparticles having a larger grain size with the semiconductor nanoparticles having the aforementioned average grain size to have the semiconductor nanoparticles having the larger grain size to scatter incident light, thereby enhancing the quantum yield. In this case, the average grain size of the semiconductor nanoparticles to be added is preferably 20-500 nm.

The semiconductor layer composed of semiconductor nanoparticles preferably has a surface area large enough to absorb as many dye particles as possible. For this purpose, the surface area of the semiconductor nanoparticle layer coated on the support structure is preferably ten times or more, or more preferably 100 times or more, of the projected area. Although there is no ceiling for the surface area, it is normally 1000 times or so. In general, as the semiconductor nanoparticle layer increases its thickness, its light-capturing rate increases because of an increase of retained due particles per unit projected area. However, because injected electrons must travel longer to diffuse, the loss by charge recombination also increases. Therefore, there is a preferable range of thickness for the semiconductor nanoparticle layer. It is generally 0.1-100 μm, more preferably 1-50 μm, and most preferably 3-30 μm. Semiconductor nanoparticles are preferably baked after being coated on the support structure to make electrical contact with each other and to improve the strength of the film and the adhesiveness with the substrate. There are no special restrictions on the range of calcination temperature. However, if the temperature is too high, it undesirably increases the substrate resistance and may result in melting the substrate. Therefore, the temperature is normally 40-700° C. and more preferably 40-650° C. The calcination time is normally from 10 minutes to 10 hours approximately, although not limitative. After calcination, for purposes of increasing the surface area of semiconductor particles, removing impurities from the semiconductor nanoparticle layer and enhancing the efficiency of electron injection from the dye into semiconductor nanoparticles, the semiconductor nanoparticle layer may undergo chemical plating using water solution of titanium tetrachloride or electrochemical plating using water solution of titanium trichloride. In addition, a conduction-assisting agent may be added to reduce the impedance of the semiconductor nanoparticle layer. In case a plastic substrate is used as the support structure of the transparent conductive layer, a paste containing a bonding agent and containing semiconductor nanoparticles dispersed therein may be formed (coated) on the substrate such that the semiconductor nanoparticles are bonded to the substrate under pressure from a heating press at 50-120° C., for example.

Any dye, having a sensitizing function, may be employed to be retained by the semiconductor nanoparticles. Examples of the dye are xanthene-based dyes such as rhodamine B, rose bengal, eosin and Erythrocin; cyanine-based dyes such as quinocyanine and cryptocyanine; basic dyes such as phenosafranine, Capri blue, thiocin and methylene blue; porphyrin-based compounds such as chlorophyll, zinc porphyrin and magnesium porphyrin; azo dyes; phthalocyanine compounds; coumarin-based compounds; ruthenium (Ru) bipyridine complex compound; anthraquinone-based dyes; and polycyclic quinone-based dyes. Among them, Ru bipyridine complex compound is preferable because of its high quantum yield. However, without being limited to it, those dyes can be used alone or as a mixture of two or more kinds of them.

The dye may be retained by the semiconductor nanoparticle layer in any form or manner. For example, a typical method dissolves any of the above-mentioned dyes in a solution such as alcohols, nitriles, nitromethane, halogenated hydrocarbon, ethers, dimethyl sulfoxide, amides, N-methylpyrrolidone, 1,3-dimethyl imidazolidinone, 3-methyl oxazolidinone, esters, carbonic acid esters, ketones, hydrocarbon, water, and so on; and next immerses the semiconductor nanoparticle layer therein, or coats the dye solution on the semiconductor nanoparticle layer. In this case, the quantity of dye molecules to be retained by the semiconductor nanoparticles is preferably in the range of 1-1000 molecules, and more preferably in the range of 1-100 molecules. If far excessive dye molecules are retained by semiconductor nanoparticles, electrons excited by light energy are not injected into semiconductor nanoparticles and rather deoxidize the electrolyte. Thus, excessive dye molecules rather invite energy loss. Therefore, it is ideal that a single dye molecule is retained by a single semiconductor nanoparticle, and the temperature and pressure for retainment can be changed if necessary. For the purpose of reducing association of dye particles, carboxylic acid such as deoxycholic acid may be added as well. It is also possible to use an ultraviolet absorbent together.

For the purpose of removing excessively retained dye particles, the semiconductor nanoparticle layer may undergo surface treatment using a kind of amine after the dye particles absorb. Examples of amine system substances are pyridine, 4-tert-butyl pyridine, polyvinyl pyridine, and so on. If they are liquids, they can be used either directly or in form of solution in an organic solvent.

Any conductive material may be used as the counter electrode. Even an insulating material can be used in combination with a conductive layer formed to face the semiconductor electrode. However, the material used as the electrode is preferably stable in electrochemical properties. In this sense, platinum, gold, carbon, or the like, is preferably used. To enhance the oxidation-reduction catalytic effect, one side of the counter electrode opposed to the semiconductor electrode preferably has a minute structure increased in surface area. For example, in case of platinum, it is preferably in the state of platinum black. In case of carbon, it is preferably in a porous state. Such a platinum black state can be made by anodic oxidation, chloroplatinic treatment, or the like. Porous carbon can be made by sintering of carbon nanoparticles, calcination of organic polymer, or the like. Alternatively, it is also acceptable to make wirings of a metal having a high oxidation-reduction catalytic effect such as platinum on the transparent conductive substrate, or treat the surface by chloroplatinic treatment, to use it as a transparent counter electrode.

The electrolyte may be a combination of iodine (I₂) and metal iodide or organic iodide, or a combination of boron (Br₂) and metal boride or organic boride. Also usable are metal chains such as ferrocyanic acid salt/ferricyanic acid salt and ferrocene/ferricynium ions, sulfur compounds such as sodium polysulfide and alkylthiol/alkyldisulfide, viologen dyes, hydroquinone/quinone, and so forth. Preferable cations of the above metal compounds are Li, Na, K, Mg, Ca, Cs, or the like, and preferable cations of the above organic compounds are quaternary ammonium compounds such as kinds of tetraalkyl ammoniums, pyridiniums, imidazoliums, and so forth. However, without being limited to them, cations may be combinations of two or more kinds of them. Among them, electrolytes combining I₂ and quaternary ammonium compounds such as LiI, NaI or imidazolium iodides, or the like, are desirable. Concentration of the electrolyte salt is preferably 0.05-5 M, or more preferably 0.2-1 M, with respect to the solvent. Concentration of I₂ and Br₂ is preferably 0.0005-1 M, or more preferably 0.001-0.1 M. To improve the open-circuit voltage and short-circuit current, various kinds of additives such as 4-tert-butyl pyridine, carboxylic acid, or the like, may be added.

The solvent composing the electrolyte composite may be selected from water, alcohols, ethers, esters, carbonic acid esters, lactones, carboxylic acid esters, phosphoric triesters, heterocyclic compounds, nitriles, ketones, amides, nitromethane, halogenated hydrocarbon, dimethyl sulfoxide, sulforan, N-methyl-pyrrolidone, 1,3-dimethyl imidazolidinone, 3-methyl oxazolidinone, hydrocarbon, and so forth, each alone, or in combination of two or more kinds of them. As the solvent, room-temperature ionic liquids of quaternary ammonium salts of tetra alkyl system, pyridinium system or imidazolium system are usable as well.

To reduce liquid leakage of the photoelectric device and vaporization of the electrolyte, it is also possible to dissolve a gelatinizer, polymer, cross-linking monomer, or the like, into the electrolyte composite to form a gel electrolyte. As to the ratio of the electrolyte composite relative and the gel matrix, if the electrolyte composite is abundant, the ion conductivity gets higher, but the mechanical strength decreases. In contrast, if the electrolyte composite is too scarce, the mechanical strength increases, but the ion conductivity decreases. Therefore, the electrolyte composite is preferably 50-99 wt %, and more preferably 80-97 wt %. It is also possible to realize a fully solid photoelectric transfer device by dissolving the electrolyte and a plasticizer into a polymer and removing the plasticizer by vaporization.

The photoelectric transfer device may be manufactured by any method. For example, the electrolyte composite may be in liquid form or may be gelatinized inside the photoelectric transfer device. In case the electrolyte is in liquid form before being introduced, the semiconductor electrode retaining the dye and the counter electrode are put together face to face, and a part of the substrate not having the semiconductor electrode is sealed such that these two electrodes do not contact. The gap between the semiconductor electrode and the counter electrode may be determined appropriately. However, it is normally 1-100 μm, or more preferably 1-50 μm. If the distance between the electrodes is too long, light current decreases due to a decrease of the conductivity. Any method can be used for the sealing. However, it is preferable to use a material excellent in resistance to light, electrical insulation and damp-proof capability. For this purpose, various methods and materials are usable, such as epoxy resins, ultraviolet-setting resins, acrylic adhesives, EVA (ethylene vinyl acetate), ionomer resins, ceramics, heat seal films, and so forth. An inlet required for introducing the solution of the electrolyte composite may be mad at any position except the position of the dye-retained semiconductor electrode and the counter electrode. The solution may be introduced by any method. However, the solution is preferably introduced inside the cell already sealed and having the solution inlet. In this case, it is an easy way to pour drops of the solution into the inlet and introduce it inside by capillary phenomenon. If desired, introduction of the solution may be conducted under reduced pressure or heat. After the solution is fully introduced, an extra amount of the solution remaining in the inlet is removed, and the inlet is sealed. Any method may be used for the sealing of the inlet. If necessary, however, a glass plate or a plastic substrate, for example, may be bonded with a sealing agent to seal the inlet. In the case of gel electrolytes and fully solid electrolytes using polymers or the like, the polymer solution containing an electrolyte composite and a plasticizer is removed by vaporization by a casting method from above the dye-retained semiconductor electrode. After the plasticizer is fully removed, the inlet is sealed in the above manner. This sealing is preferably conducted in a vacuum sealer, or the like, providing an inactive gas atmosphere or a reduced pressure. After the sealing, heat or pressure may be applied, if necessary to impregnate the semiconductor nanoparticle layer with the electrolyte.

The photoelectric transfer device may be fabricated in various forms suitable for their use, without being limited to specific forms.

According to the invention having the above construction, since it uses the transparent conductive substrate made by stacking the transparent substrate, conductive wiring layer and protective layer such as a metal oxide layer in order from the light-receiving side and having sheet resistance equal to or less than 10Ω/□, in which the conductive wiring layer and the electrolyte are not in direct contact, it not only prevents reverse electron transfer reaction but also prevents corrosion of the conductive wiring layer. Thus, the invention can realize a photoelectric transfer device excellent in durability and photoelectric transfer efficiency.

### BRIEF DESCRIPTION OF DRAWINGS

FIG. 1 is a cross-sectional view showing a dye-sensitized wet photoelectric transfer device according to an embodiment of the invention;

FIG. 2 is a cross-sectional view of the part of the conductive wiring layer in the dye-sensitized wet photoelectric transfer device according to the first embodiment of the invention; and

FIG. 3 is a plan view of a substantial part of the dye-sensitized wet photoelectric transfer device according to the first embodiment of the invention.

### BEST MODE FOR CARRYING OUT THE INVENTION

An embodiment of the invention will now be explained below with reference to the drawings.

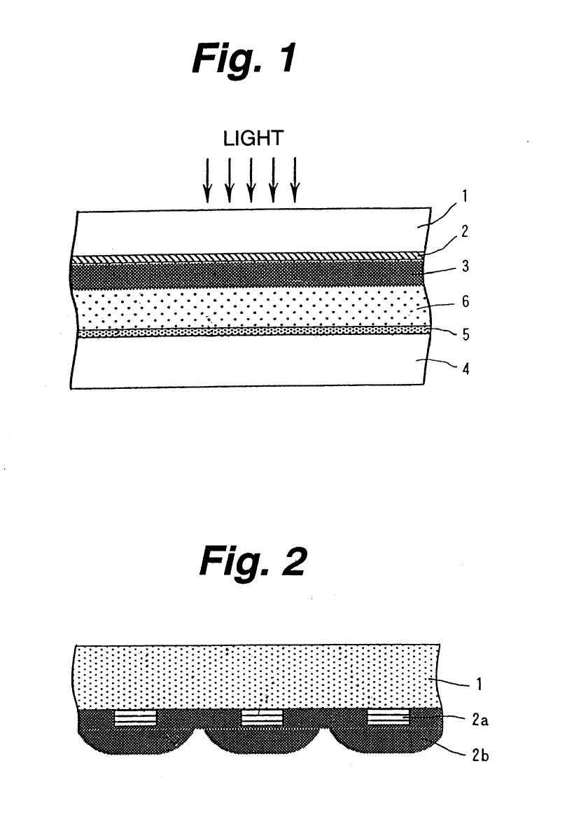

FIG. 1 shows a dye-sensitized wet photoelectric transfer device according to an embodiment of the invention.

As shown in FIG. 1, in the dye-sensitized wet photoelectric transfer device, a transparent substrate 1, having a semiconductor nanoparticle layer 3 (semiconductor electrode) retaining a sensitizing dye on its major surface via a semiconductor wiring layer/metal oxide layer 2, and a transparent conductive substrate 4, having a platinum or platinum catalyst layer 5 on its major surface, are put together such that the semiconductor nanoparticle layer 3 and the platinum or platinum catalyst layer 5 face to each other via a predetermined distance. In a space between them, an electrolyte layer (electrolytic solution) 6 is enclosed.

FIG. 2 shows details of the conductive wiring layer/metal oxide layer 2 stacked on the major surface of the transparent substrate 1. As shown in FIG. 2, the transparent substrate 1, conductive wiring layer 2a and metal oxide layer 2b are stacked in order from the light-receiving side to form the transparent conductive substrate having sheet resistance equal to or less than 10Ω/□. The conductive wiring layer 2a is fully covered by the metal oxide layer 2 integrally deposited on the entire substrate surface.

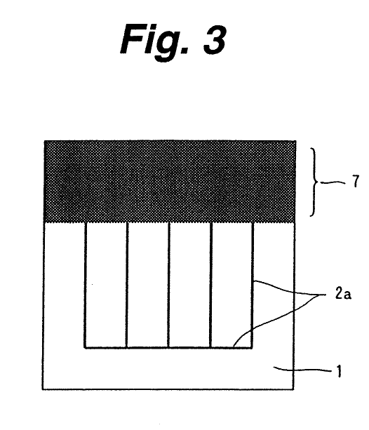

FIG. 3 shows a plan view (projected figure) of the dye-sensitized wet photoelectric transfer device, taken from the light-receiving side of the transparent conductive substrate. The conductive wiring layer 2a is connected to a collector portion 7.

Materials of the transparent substrates 1, conductive wiring layer 2a, metal oxide layer 2b, semiconductor nanoparticle layer 3, transparent conductive substrate 4 and electrolyte layer 6 may be selected appropriately from the materials already introduced herein.

Next explained is a manufacturing method of the dye-sensitized wet photoelectric transfer device.

First prepared is the transparent substrate 1. Next, the conductive wiring layer 2a of a predetermined pattern is formed on the transparent substrate 1 by lithography, lift-off, or the like. Thereafter, the metal oxide layer 2b is formed on the entire surface of the transparent substrate 1 to cover the conductive wiring layer 2a. After that, a paste with dispersed semiconductor nanoparticles is coated on the metal oxide layer 2b to a predetermined gap (thickness). Then, the semiconductor nanoparticles are sintered by heat of a predetermined temperature for a predetermined time. As a result, the semiconductor nanoparticle layer 3 is formed on the metal oxide layer 2b. After that, the semiconductor nanoparticle layer 3 is immersed into a dye solution, for example, to have it retain the dye.

On the other hand, the transparent conductive substrate 4 is prepared separately, and a platinum or platinum catalyst layer 5 is formed thereon.

In the next step, the transparent substrate 1, having the conductive wiring layer 2a, metal oxide layer 2b and dye-retained semiconductor nanoparticle layer 3 thereon, and the transparent conductive substrate 4 are put together such that the semiconductor nanoparticle layer 3 and the platinum or platinum catalyst layer 5 face to each other via a distance of 1-100 μm or preferably 1-50 μm and a space for receiving the electrolyte layer 6 by using a predetermined sealing member. Then, the electrolyte layer 6 is introduced into the space through an inlet previously made, and the inlet is closed thereafter. As a result, the dye-sensitized wet photoelectric transfer device is completed.

Next explained are operations of the dye-sensitized wet photoelectric transfer device.

Incident light entering from and passing through the transparent substrate 1 excites the sensitizing dye retained on the surface of the semiconductor nanoparticle layer 3, and generates electrons. The electrons are quickly delivered from the sensitizing dye to the semiconductor nanoparticles of the semiconductor nanoparticle layer 3. On the other hand, the sensitizing dye having lost the electrons again receives electrons from ions of the electrolyte layer 6, and molecules having delivered the electrons again receive electrons at the platinum or platinum catalyst layer i5 of the counter electrode. Through this series of actions, electromotive force is generated between the transparent conductive substrate, which is composed of the sequentially stacked transparent substrate 1, conductive wiring layer 2a and metal oxide layer 2b and electrically connected to the semiconductor particle layer 3, and the transparent conductive substrate 4 electrically connected to the platinum or platinum catalyst layer 5. Photoelectric transfer takes place in this manner.

As explained above, according to this embodiment, since it uses the transparent conductive substrate made by stacking the transparent substrate 1, conductive wiring layer 2a and metal oxide layer 2b from the light-receiving side, and thereby prevents direct contact between the conductive wiring layer 2a and the electrolyte 6 in order, it can prevent not only the reverse electron transfer reaction but also corrosion of the conductive wiring layer 2a. Thus, the embodiment can realize the dye-sensitized wet photoelectric transfer device, in particular, a dye-sensitized wet solar cell, which is excellent in durability and photoelectric transfer efficiency.

Some practical examples of the dye-sensitized wet photoelectric transfer device are explained below. Conditions of the examples are shown in Table 1 together with conditions of comparative examples. In addition, results of measurement of the practical examples are shown in Table 2 together with results of measurement of the comparative examples.

TABLE 1

| | Conductive wiring Layer | Metal Oxide Layer |
|---|---|---|
| Example 1 | Ru 4500Δ/Cr 500Δ | ITO 4500Δ/SnO₂ 500Δ |
| Example 2 | Ru 4500Δ/Cr 500Δ | FTO 5000Δ |
| Example 3 | Ru 4500Δ/Cr 500Δ | ITO 4500Δ/TiO₂ 200Δ |
| Example 4 | Ru 4500Δ/Cr 500Δ | ITO 4500Δ/ZnO₂ 200Δ |
| Example 5 | Pt 4500Δ/Cr 500Δ | ITO 4500Δ/SnO₂ 500Δ |
| Example 6 | Au 4500Δ/Cr 500Δ | ITO 4500Δ/SnO₂ 500Δ |
| Example 7 | Os 4500Δ/Cr 500Δ | ITO 4500Δ/SnO₂ 500Δ |
| Example 8 | Ti 5000Δ | ITO 4500Δ/SnO₂ 500Δ |
| Example 9 | Ni 4500Δ/Cr 500Δ | ITO 4500Δ/SnO₂ 500Δ |
| Example 10 | Cr 5000Δ | ITO 4500Δ/SnO₂ 500Δ |
| Example 11 | Cu 4500Δ/Cr 500Δ | ITO 4500Δ/SnO₂ 500Δ |
| Example 12 | Ag 4500Δ/Cr 500Δ | ITO 4500Δ/SnO₂ 500Δ |
| Example 13 | Pd 4500Δ/Cr 500Δ | ITO 4500Δ/SnO₂ 500Δ |
| Example 14 | In 4500Δ/Cr 500Δ | ITO 4500Δ/SnO₂ 500Δ |
| Example 15 | Zn 4500Δ/Cr 500Δ | ITO 4500Δ/SnO₂ 500Δ |
| Example 16 | Mo 4500Δ/Cr 500Δ | ITO 4500Δ/SnO₂ 500Δ |
| Example 17 | Al 5000Δ | ITO 4500Δ/SnO₂ 500Δ |
| Example 18 | C 4500Δ/Cr 500Δ | ITO 4500Δ/SnO₂ 500Δ |
| Comparative 1 | Ru 4500Δ/Cr 500Δ | None |
| Comparative 2 | Pt 4500Δ/Cr 500Δ | None |
| Comparative 3 | Au 4500Δ/Cr 500Δ | None |
| Comparative 4 | Os 4500Δ/Cr 500Δ | None |
| Comparative 5 | Ti 5000Δ | None |
| Comparative 6 | Ni 4500Δ/Cr 500Δ | None |
| Comparative 7 | Cr 5000Δ | None |
| Comparative 8 | Cu 4500Δ/Cr 500Δ | None |
| Comparative 9 | Ag 4500Δ/Cr 500Δ | None |
| Comparative 10 | Pd 4500Δ/Cr 500Δ | None |
| Comparative 11 | In 4500Δ/Cr 500Δ | None |
| Comparative 12 | Zn 4500Δ/Cr 500Δ | None |
| Comparative 13 | Mo 4500Δ/Cr 500Δ | None |
| Comparative 14 | Al 5000Δ | None |
| Comparative 15 | C 4500Δ/Cr 500Δ | None |
| Comparative 16 | None | ITO 4500Δ/SnO₂ 500Δ |
| Comparative 17 | None | FTO 5000Δ |
| Comparative 18 | None | ITO 4500Δ/TiO₂ 200Δ |
| Comparative 19 | None | ITO 4500Δ/ZnO₂ 200Δ |

TABLE 2

| | Just After Made | One Month Later |
|---|---|---|
| Example 1 | 7.9% (◯) | 7.5% (◯) |
| Example 2 | 7.3% (◯) | 6.9% (◯) |
| Example 3 | 6.5% (◯) | 6.2% (◯) |
| Example 4 | 6.4% (◯) | 6.2% (◯) |
| Example 5 | 7.5% (◯) | 7.2% (◯) |
| Example 6 | 7.6% (◯) | 7.4% (◯) |
| Example 7 | 7.3% (◯) | 7.0% (◯) |
| Example 8 | 7.7% (◯) | 7.5% (◯) |
| Example 9 | 7.7% (◯) | 7.4% (◯) |
| Example 10 | 7.5% (◯) | 7.0% (◯) |
| Example 11 | 7.6% (◯) | 7.2% (◯) |
| Example 12 | 7.7% (◯) | 7.3% (◯) |
| Example 13 | 7.2% (◯) | 7.1% (◯) |
| Example 14 | 7.1% (◯) | 6.8% (◯) |
| Example 15 | 7.5% (◯) | 7.1% (◯) |
| Example 16 | 7.4% (◯) | 7.2% (◯) |
| Example 17 | 7.7% (◯) | 7.4% (◯) |
| Example 18 | 6.2% (◯) | 5.9% (◯) |
| Comparative 1 | 1.5% (◯) | 0.2% (Δ) |
| Comparative 2 | 1.1% (◯) | 0.3% (Δ) |
| Comparative 3 | 1.2% (◯) | Inoperative (X) |
| Comparative 4 | 1.1% (◯) | 0.2% (X) |
| Comparative 5 | 1.3% (◯) | 0.2% (Δ) |
| Comparative 6 | 1.2% (◯) | 0.3% (X) |
| Comparative 7 | 1.1% (◯) | Inoperative (X) |
| Comparative 8 | 1.4% (◯) | Inoperative (X) |
| Comparative 9 | 1.2% (◯) | Inoperative (X) |
| Comparative 10 | 1.1% (◯) | 0.1% (X) |
| Comparative 11 | 1.3% (◯) | 0.1% (X) |
| Comparative 12 | 1.2% (◯) | Inoperative (X) |
| Comparative 13 | 1.0% (◯) | 0.2% (X) |
| Comparative 14 | 0.5% (◯) | Inoperative (X) |
| Comparative 15 | 0.8% (◯) | 0.1% (Δ) |
| Comparative 16 | 1.5% (—) | 1.4% (—) |
| Comparative 17 | 1.5% (—) | 1.4% (—) |
| Comparative 18 | 0.5% (—) | 0.4% (—) |
| Comparative 19 | 0.5% (—) | 0.3% (—) |

Marks in parentheses indicate the following conditions.
◯: Good (Unchanged)
Δ: Partly dissolved
X: Fully dissolved

### Example 1

TiO₂ nanoparticles were used as semiconductor nanoparticles. Referring to known methods (H. Arakawa, “Latest Techniques of Dye-sensitized Solar Cells” (C.M.C.) p. 45-47 (2001)), paste with dispersed nanoparticles was prepared as follows. 125 ml of titanium isopropoxide was seeped slowly into 750 ml of 0.1M nitric acid water solution while stirring it at the room temperature. After the seeping, the solution was moved to a constant temperature bath held at 80° C. and stirred therein for 8 hours. Thereby, Thereby, a cloudy, semi-transparent sol solution was obtained. The sol solution was left to cool down to the room temperature, then filtered through a glass filter, and 700 ml thereof was measured up. The sol solution obtained was moved to an autoclave, then annealed at 220° C. for 12 hours, and thereafter dispersed by ultrasonic treatment for one hour. Subsequently, the solution was condensed by an evaporator at 40° C. until the content of TiO₂ becomes 20 wt %. The condensed sol solution was added with polyethylene glycol (having the 500 thousand molecular mass) by 10 wt % relative to the weight of TiO₂ in the paste, and mixed homogenously in a planet ball mill to obtain a viscosity-enhanced TiO₂ paste.

Also prepared was a transparent conductive glass substrate (having the sheet resistance of 1Ω/□ and sized 30 mm each side) as the transparent substrate 1 by stacking in order a 1.1 mm thick substrate of soda lime glass, a 450 nm thick Ru layer as the conductive wiring layer 2a (wirings 200 μm wide each, with the line-to-line distance of 5 mm on a 50 nm thick base), a 450 nm thick ITO layer, and a 50 nm thick SnO₂ layer as the metal oxide layer 2b. The TiO₂ paste already prepared was coated on the transparent conductive glass substrate by blade coating over the area of 20 mm×15 mm while making the cap of 200 μm, and held at 450° C. for 30 minutes. Thereafter, TiO₂ was sintered on the transparent conductive glass substrate.

After that, the substrate was immersed in a dehydrated ethanol solution in which 0.5 mM of cis-bis(isothiocyanate)-N,N-bis(2,2′-dipyridile)-4,4′-dicarboxylic acid)-ruthenium (II) dihydrate and 20 mM of deoxycholic acid for 12 hours to have the dye retained. This electrode was washed first by ethanol solution of 4-tert-butyl pyridine and next by dehydrated ethanol, and dried in a dark place.

The counter electrode used was prepared by sputtering 100 nm thick platinum on fluorine-doped conductive glass substrate (sheet resistance: 10Ω/□) previously having formed 1 mm sized inlet, then seeping drops of ethanol solution of chloroplatinic acid on the platinum, and heating it to 385° C.

The prepared dye-retained TiO₂ nanoparticle layer, i.e. the semiconductor electrode, was placed face to face with the platinum surface of the counter electrode, and their outer circumference was sealed with a 30 μm thick EVA film and epoxy adhesive.

On the other hand, an electrolyte composite was prepared by dissolving 0.04 g of lithium iodide (LiI), 0.479 g of 1-propyl-2,3-dimethyl imidazolium iodide, 0.0381 g of iodine (I₂) and 0.2 g of 4-tert-butyl pyridine into 3 g of methoxypropionitrile.

The above mixed solution was introduced into the device by seeping drops thereof into the inlet of the device prepared and reducing the pressure, and the inlet was sealed by an EVA film, epoxy adhesive and glass substrate. Thus, the photoelectric transfer device was completed.

### Examples 2 to 18 and Comparative Examples 1 to 19

In Examples 2 to 18, photoelectric transfer devices were prepared in the same manner as Example 1 except the use of the transparent conductive substrate having the conductive wiring layer and the metal oxide layer shown in Table 1. In Comparative Examples 1 to 15, photoelectric transfer devices were prepared in the same manner as Example 1 except the use of the transparent conductive substrate having the conductive wiring layer shown in Table 1 but not having the metal oxide layer. In Comparative Examples 16 to 19, photoelectric transfer devices were prepared in the same manner as Example 1 except the use of the transparent conductive substrate not having the conductive wiring layer.

With the dye-sensitized wet photoelectric transfer devices according to Examples 1 to 18 and Comparative Examples 1 to 19, photoelectric transfer efficiency responsive to irradiation of false sunlight (AM 1.5, 100 mW/cm²) was measured just after and one month later than fabrication of the devices. Throughout the period of measurement, the photoelectric transfer devices are exposed to ultraviolet light and held at room temperatures.

Conditions of the photoelectric transfer devices were examined by visual observation.

Results of the measurement are shown in Table 2.

It is appreciated from Table 2 that the dye-sensitized wet photoelectric transfer devices according to Examples 1 to 18 have been improved remarkably and much more excellent in durability by the structure stacking the conductive wiring layer 2a and the metal oxide layer 2b in comparison with the dye-sensitized wet photoelectric transfer devices according to Comparative Examples 1 to 19 using transparent conductive substrates not having conductive wiring layers or metal oxide layers.

Heretofore, an embodiment and practical examples of the present invention have been explained. However, the invention is not limited to these embodiment and practical examples, but contemplates various changes and modifications based on the technical concept of the invention.

Fog example, the numerical values, structures, shapes, materials, source materials, processes, and so on, are mere examples, and any other appropriate numerical values, structures, shapes, materials, source materials, processes, and so on, may be used, if necessary.

More specifically, although the practical examples immerse the substrate already having the semiconductor nanoparticle layer formed thereon in a dye solution to have the dye retained on semiconductor nanoparticles, a paste of semiconductor nanoparticles already retaining the dye may be coated.

As described above, according to the invention, since it uses the transparent conductive substrate made by stacking the transparent substrate, conductive wiring layer and protective layer in order from the light-receiving side and having sheet resistance equal to or less than 10Ω/□, it can realize a photoelectric transfer device free from reverse electron transfer reaction and enhanced in durability and photoelectric transfer efficiency.

1. A photoelectric transfer device comprising:
a transparent conductive substrate made by stacking a transparent substrate, a conductive wiring layer, and a protective layer in order from the light-receiving side, the transparent conductive substrate having a sheet resistance equal to or lower than 10Ω/□,
wherein the protective layer comprises materials selected from a group consisting of ITO and SnO₂ formed on the ITO, ITO and TiO₂ formed on the ITO, and ITO and ZnO formed on the ITO.

2. The photoelectric transfer device according to claim 1 wherein the protective layer is transparent and electrically conductive.

3. The photoelectric transfer device according to claim 1 wherein the protective layer comprises a metal oxide layer.

4. The photoelectric transfer device according to claim 3 wherein the metal oxide layer is made of at least one kind of metal oxide selected from the group consisting of In—Sn composite oxides, SnO₂, TiO₂ and ZnO.

5. The photoelectric transfer device according to claim 3 wherein thickness of the metal oxide layer is in a range from 10 nm to 1000 nm.

6. The photoelectric transfer device according to claim 1 further comprising:
a collector portion,
wherein the conductive wiring layer comprises a plurality of wires arranged on the transparent conductive substrate, and at least one wire of the plurality of wires is electrically connected to the collector portion.

7. The photoelectric transfer device according to claim 1 wherein the conductive wiring layer is made of an electrically conductive material containing at least an element selected from the group consisting of Pt, Au, Ru, Os, Ti, Ni, Cr, Cu, Ag, Pd, In, Zn, Mo, Al and C.

8. The photoelectric transfer device according to claim 1 wherein thickness of the conductive wiring layer is in a range from 50 nm to 5000 nm.

9. The photoelectric transfer device according to claim 1 wherein a ratio of area covered by the conductive wiring layer relative to a light-receiving portion of the photoelectric transfer device is in a range from 0.1% to 20%.

10. The photoelectric transfer device according to claim 1 wherein width of each line of the conductive wiring layer is in a range from 10 μm to 500 μm.

11. The photoelectric transfer device according to claim 1 wherein distance between adjacent lines of the conductive wiring layer is in a range from 1 mm to 50 mm.

12. The photoelectric transfer device according to claim 1 wherein a semiconductor layer and an electrolyte layer are provided between the transparent conductive substrate and a conductive substrate as a counter electrode thereof to generate electrical energy between the transparent conductive substrate and the conductive substrate by photoelectric transfer.

13. The photoelectric transfer device according to claim 1 wherein the photoelectric transfer device is configured as a dye-sensitized wet solar cell.

14. The photoelectric transfer device according to claim 1 wherein the protective layer comprises ITO and SnO₂ formed on the ITO.

15. The photoelectric transfer device according to claim 1 wherein the protective layer comprises ITO and TiO₂ formed on the ITO.

16. The photoelectric transfer device according to claim 1 wherein the protective layer comprises ITO and ZnO formed on the ITO.

17. The photoelectric transfer device according to claim 7 wherein the electrically conductive material contains at least an element selected from the group consisting of Ru, Ag, and Al.

18. The photoelectric transfer device according to claim 17 wherein the electrically conductive material contains Ru.

19. The photoelectric transfer device according to claim 17 wherein the electrically conductive material contains Ag.

20. The photoelectric transfer device according to claim 17 wherein the electrically conductive material contains Al.
